(19) United States
(12) Patent Application Publication
(10) Pub. No.: US 2009/0007954 A1
(43) Pub. Date: Jan. 8, 2009

(54) Temperature differential panel

(76) Inventor: Man-Huang Chen, Taipei (TW)

Correspondence Address: SALLY CHANG, 7F, NO. 3, ALLEY 32, SEC. 6 CHUNG-HSIAO EAST RD., TAIPEI, TAIWAN, R.O.C. 115, TAIPEI, 115, TW

(21) Appl. No.: 11/907,007

(22) Filed: Oct. 9, 2007

(30) Foreign Application Priority Data
Jul. 2, 2007 (TW) 096124026

(51) Int. Cl. H01L 35/28

(52) U.S. Cl. 136/241; 136/200; 136/236.1

(57) ABSTRACT

The present invention is related to a temperature differential panel with conductors made of different metals or alloys. With thermoelectric couple effects the panel and device can generate power by temperature difference. The temperature differential panel comprises a sheet-like insulation (3); and a current power generation device (2) consists of a plurality of first conductors (20) and second conductors (21) made of different metals or alloys, the first conductors (20) and second conductors (21) are disposed to a top and a bottom of the sheet-like insulation (3) respectively; each of both ends of the first conductors (20) are connected to each of both ends of the second conductors (21) respectively to form electric charging points (22a, 22b).

### FIELD OF THE INVENTION

This present invention relates to a temperature differential panel based on easy configuration.

### BACKGROUND INVENTION

While we consume fossil fuels, the carbon dioxide emission increased in the air at the same time. It is said that we have converted our coal mine etc., into carbon dioxide which contained in the air and if increased two-folds as much as before, mother earth's surface temperature may rise 4˜5° C. as contributor of global warming. Thus energy consumption is directly associated with environmental problems after getting worse for decades it may also lead to human-made disasters. Hurricane Katrina flooded New Orleans in August 2005 might be a good example to explain. Therefore how to use our energy resource effectively become a concerned agenda. Since carbon dioxide emission is already concerned as a contributor to human-made environmental disaster. Manufacturers develop new power generating methods, such as thermo-electric module (TE) which converts heat into electric current. Since temperature gradient formed between two dissimilar conductors produce voltage, and temperature gradient in a conducting material result in heat flow and diffusion of charge carriers. People skilled in the art have provided thermoelectric module (TE) elements absorbing heat or emitting heat when electric current flowing. Since flow of charge carriers to low-temperature region creates a voltage difference so that TE elements can generate power at a temperature difference. Thermoelectric modules manufactured today consist of P-doped and N-doped bismuth-telluride semiconductors alternatively and electrically connected in series, normally is operated under high temperature for generating power.

### SUMMARY OF THE INVENTION

Thermo-electric elements in present are made by semiconductors, although thermo-electric modules have advantage in solid state but being accompanied by more disadvantages such as low electric efficiency (heat converted into only 7-8% power), space-occupied and easy to damage. Conventional thermoelectric module is built in large dimension, must be detachably operated under high temperature (250° C.); even some thermoelectric modules inefficiently operated under normal indoor temperature with low electric efficiency and a limited lifespan. But costs and malfunction rate are remaining high, and it is hard to repair, or to recycle.

Accordingly, how to extract electricity power with high electric efficiency, reduce cost of production, extend lifespan, and operate in high working temperature with various body sizes incorporated with TE elements, further the components can be recycled and reused are concerned by users.

The invention is to provide a temperature differential panel generates significant quantities of power based on Thomas Seebeck effect, the panel consists of conductors made of different metals or alloys.

To solve prior problems, a temperature differential panel comprises:

a sheet-like insulation (3); and

a current power generation device (2) consists of a plurality of first conductors (20) and a plurality of second conductors (21) made of different metals or alloys, the first conductors (20) and second conductors (21) are disposed to a top and a bottom of the sheet-like insulation (3) respectively; both ends of each the first conductors (20) are connected to both ends of each the second conductors (21) respectively to form electric charging points (22a, 22b).

A temperature differential panel (1) as mentioned above characterized in that: the temperature differential panel (1) has two thermal conductors (4) flanged along both lateral sides of the sheet-like insulation (3) shielding the electric charging points (22a, 22b); and a thermal insulator (5) shielding the first conductors (20) and second conductors (21) between two thermal conductors (4) except the electric charging points (22a, 22b).

A temperature differential panel (1) as mentioned above characterized in that: a thermal conductor (4) is composed of an insulation layer (41) shields the electric charging points (22a, 22b), a thermal conduction layer (40) shields the insulation layer (41), a thermally conductive adhesive (42) (i.e. epoxy) filled up a gap between the thermal conductive layer (40) and the electric charging points (22a, 22b).

A temperature differential panel (1) as mentioned above characterized in that: both ends of the temperature differential panel (1) have a first, a second conductive cords (6a, 6b) to discharge positive and negative charges of the current power generation device (2).

A temperature differential panel (1) as mentioned above characterized in that: the first conductive cord (6a) connected to a proximal end of the current power generation device (2) by the first conductor (20) and a second conductive cord (6b) connected to a distal end of the current power generation device (2) by the second conductor (21).

A temperature differential panel (1) as mentioned above characterized in that: materials of the first conductor (20) and the second conductor (21) are selected from one of following: chromium-magnesium alloy, aluminum-magnesium alloy; nickel-copper alloy, iron, platinum-rhodium alloy, and platinum.

A temperature differential panel (1) as mentioned above characterized in that: materials of the first conductor (20) and the second conductor (21) are metals and alloys processed through nano-scale or micro-scale treatments.

Another embodiment of a temperature differential panel (1) characterized in that:

a sheet-like insulation (3); and

a current power generation device (2) is composed of a plurality of first conductors (20) and a plurality of second conductors (21) made of different metals or alloys, each of the first conductors (20) are alternatively arranged approximately in parallel to each of the second conductors (21) in order disposed to an upper side of the insulator (3), both ends of each the first conductors (20) are connected to both ends of each the second conductors (21) respectively to form electric charging points (22a, 22b).

Two thermal conductors (4) shielding the electric charging points (22a, 22b); and a thermal insulator (5) shielding the first conductors (20) and the second conductors (21) between two thermal conductors (4) except the electric charging points (22a, 22b).

A temperature differential panel (1) as mentioned above characterized in that: materials of the first conductors (20) and the second conductors (21) are selected from one of following: chromium-magnesium alloy, aluminum-magnesium alloy; nickel-copper alloy, iron, platinum-rhodium alloy, and platinum.

A temperature differential panel (1) as mentioned above characterized in that: the materials of first conductor (20) and second conductor (21) are metals or alloys processed through nano-scale or micro-scale treatments.

A temperature differential panel (1) as mentioned above characterized in that: all the first conductors (20) and all the second conductors (21) are shaped as distinct metal membranes show laminated structure.

A temperature differential panel (1) as mentioned above characterized in that: a thermal conductor (4) consists of epoxy contained aluminum oxide, or silicon to provide excellent electrical conductivity.

A temperature differential panel (1) as mentioned above characterized in that: the temperature differential panel (1) has a first and a second conductive cords (6a, 6b) at a proximal and distal ends to discharge positive, negative charges of the current power generation device (2) respectively.

A temperature differential panel (1) as mentioned above characterized in that: the first conductive cord (6a) is connected to a proximal end of the current power generation device (2) by the first conductor (20), the second conductive cord (6b) is connected to a distal end of the current power generation device (2) by the second conductor (21).

To solve prior problems, a temperature differential accumulator characterized in that:

A plurality of temperature differential panels (1) disposed to an upper surface of a substrate (9), the conductive cords (6a, 6b) connected to right and left ends of the current power generation devices (2) discharging positive and negative charges respectively can be in connection with one another to form major conductive cords (6A, 6B) discharging positive and negative charges.

A temperature differential accumulator as mentioned above characterized in that: each of the plurality of temperature differential panels (1) as claim 1 claimed.

A temperature differential accumulator as mentioned above characterized in that: each of the plurality of temperature differential panels (1) as claim 8 claimed.

A temperature differential accumulator as mentioned above characterized in that: materials of the substrate (9) have high coefficient of heat transferring.

A temperature differential accumulator as mentioned above characterized in that: the substrate (9) can be added to the thermal conductor (4) on top of the temperature differential panels (1).

### Advantage of Embodiments of the Invention

The invention can be embodied to achieve advantages as following:

1. Metals such as iron can be prepared as bulk thermoelectric material applied to current power generation, cost of production can be reduced, procedures of production is much easier, too. The entire current power generation is more efficient and not easy to damage or malfunctioning.

2. Configuration of each temperature differential panel is not only simply constituted by the same individual/repetitive sheets, but also more temperature differential panels can be integrated with one another sequentially. As printed circuit board (PCB) can be minimized to a chip, each of the temperature differential panel can be also dimensioned as a chip so as to enable the size of the same individual/repetitive sheets to be further integrated to create smaller temperature differential panels than ever. Manufacturing thermoelectric (TE) elements are allowed to make various sizes according to requirements of different devices. Moreover the TE element of the present invention is able to suit all kind of occasions or scales.

3. Threshold value of manipulating temperature of the invention is more feasible than conventional thermo-electric module, which can be operated under normal indoor temperature up to 250° C. While the TE elements of the invention are able to work under temperature lower as −273° C. up to 300° C. It is flexible to use in all kind of devices and occasions with high electric efficiency under high temperature.

4. Entire configuration can be more durable during usage because dynamic element is not found incorporated to the temperature differential accumulator which discharges direct current. Nor dynamic element matching technique is required. It leads to a lower breakdown or malfunction ratio to the TE element of the invention. Furthermore, individual/repetitive sheets are easily maintained or replaced even can be recycled or reused when retrieving malfunctioned temperature differential panels (i.e. TE elements) back to the manufacturers.

5. First conductor and second conductor are processed through nano-scale or micro-scale treatments; since nano-scale thermoelectric material is endowed with new physical properties developing into nano surface area technology. However, micro-scale thermoplastic material is adopted to facilitate chip processing and enhance high electric efficiency as well as saving more capital investment than conventional thermo-electric modules.

### BRIEF DESCRIPTION OF THE DRAWINGS

FIG. 1: shows a perspective view of the temperature differential panel of the invention;

FIG. 2: shows a sectional view of FIG. 1 in part;

FIG. 3: shows an enlarged sectional view of FIG. 2 indicated by a circle;

FIG. 4: shows a cross sectional view of FIG. 1 indicated at IV-IV;

FIG. 5: shows a cross sectional view of FIG. 1 indicated at V-V;

FIG. 6: shows a top view of FIG. 1;

FIG. 7: shows a schematic view of embodiment of the temperature differential panel of the invention;

FIG. 8: shows a schematic view of another embodiment of the invention;

FIG. 9: shows a cross sectional view of FIG. 8 indicated at IX-IX; and

FIG. 10: shows a schematic view of another embodiment of the invention;

### DETAILED DESCRIPTION OF THE PREFERRED EMBODIMENTS

Description of the invention is described in detail according to the appended drawings hereinafter.

### First Embodiment

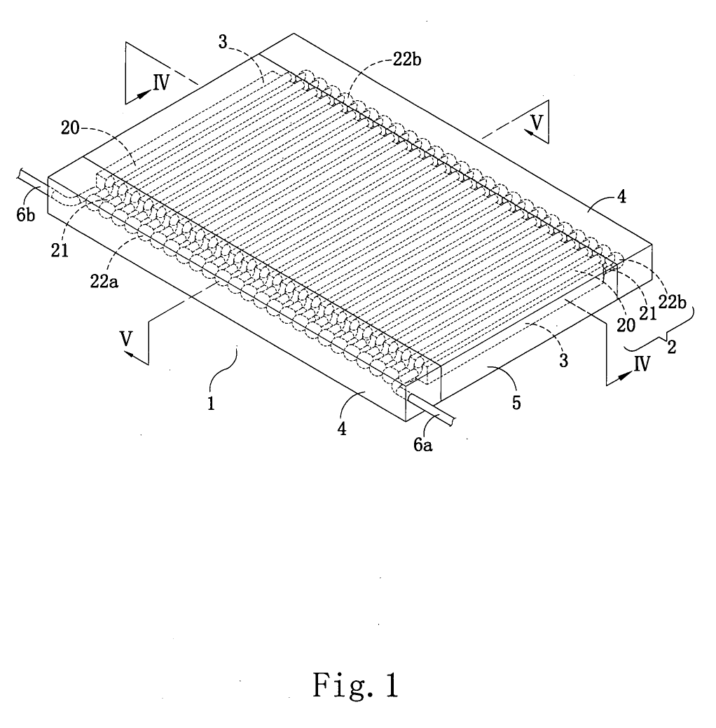

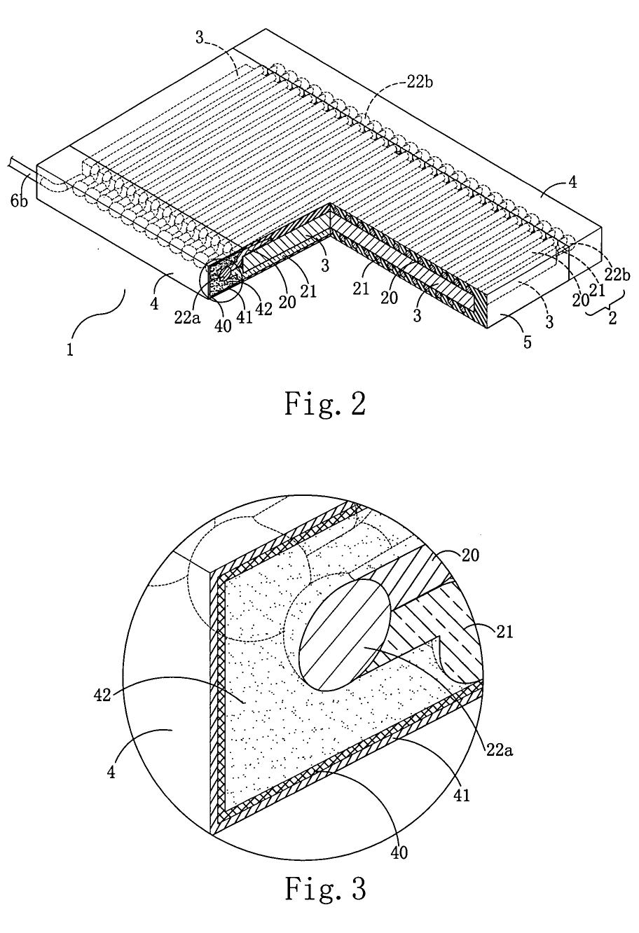

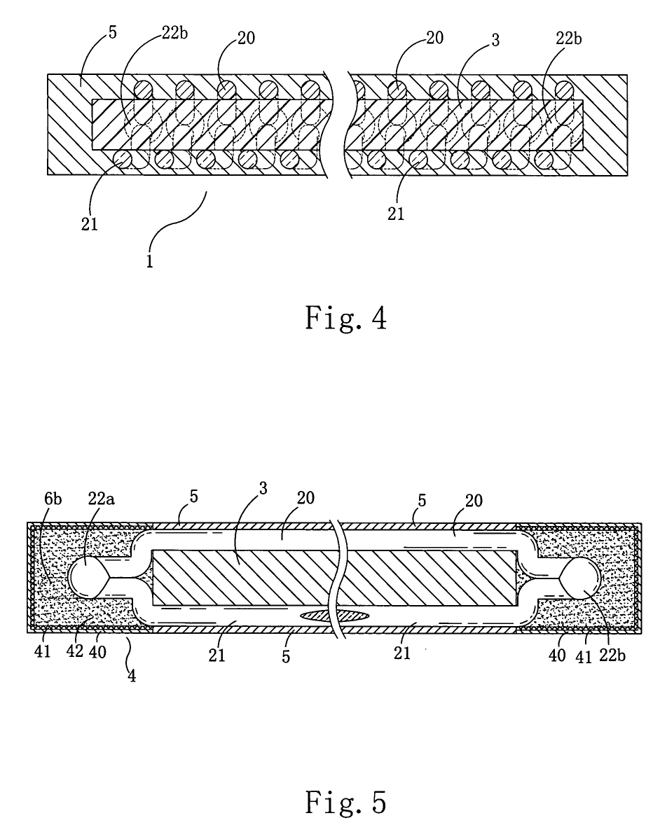

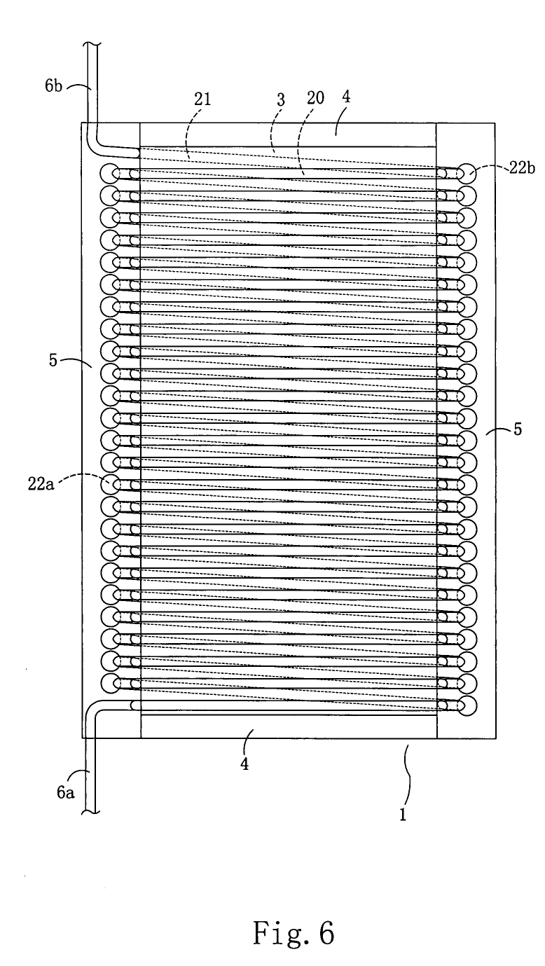

As shown in FIGS. 1˜6, a temperature differential panel is illustrated. The temperature differential panel (1) characterized in that;

a sheet-like insulation (3); and

a current power generation device (2) consists of a plurality of first conductors (20) and a plurality of second conductors (21) made of different metals or alloys, the first conductors (20) and second conductors (21) are set on the top and a bottom of the insulator (3) respectively; both ends of each the first conductors (20) are connected to both ends of each the second conductors (21) respectively to form electric charging points (22a, 22b).

The first conductors (20) and second conductors (21) are made of different metals or alloys to form a thermoelectric couple put into ambient environment with temperature gradient (i.e. a top portion gives off heat to a bottom portion), it will be formed a thermoelectric generation (TEG). Under such circumstance, due to Thomas Seebeck effect (or thermoelectric effect), it may generate electric current, heat converted into electric power.

Next, because the first, second conductors (20,21) separately disposed to the top and the bottom of the sheet-like insulation, quantities of the first, second conductors (20, 21) can be decided approximately by same surface area of the insulation divided by widths of each conductor. Thereby, more conductors can be aggregated on the sheet-like insulation than bulky semi-conductor TE elements.

Furthermore, power generated at both ends of the thermoelectric couple because the first, second conductors (20, 21) aggregated on both top and bottom of the sheet-like insulation opposite to each other in pair respectively, each pair of first and second conductors (20, 21) form a pair of electric charging points (22a, 22b). Aggregate of distinct conductors (20, 21) can bridge more electric charging points (22a, 22b) with high electric efficiency.

The temperature differential panel (1) is further flanged with two thermal conductors (4) shielding both ends of the first, second conductors (20, 21); and clad with one thermal insulator (5) shielding the first, second conductors (20, 21) between the two thermal conductors (4) but the electric charging points (22a, 22b) are not included.

Not only heat absorbed into the temperature differential panel (1) by the thermal conductors (4), but also the electric charging points (22a, 22b) sealed by the thermal conductors (4) so as not to inflict any damages to the temperature differential panel (1).

Next, the thermal insulator (5) is able to shield the first, second conductors (20, 21) (electric charging points are not included) not sealed by the thermal conductors (4) so that the electric charging points (22a, 22b) do not transfer heat to the first, second conductors (20, 21). All the electric charging points (22a, 22b) shielded by the thermal conductors are therefore temporarily idle, without any exchange of heat in an isothermal process. If the temperature stays constant, no current power can be generated.

The thermal conductor (4) is composed of an insulation layer (41) shielding the electric charging points (22a, 22b), a thermal conduction layer (40) shielding the insulation layer (41), and a thermally conductive adhesive (42), namely epoxy, filled up a gap between the thermal conduction layer (40) and the electric charging points (22a, 22b). Only an insulation layer (41) is applied to prevent the electric charging points (22a, 22b) contacting with the thermal conduction layer (4). Otherwise, it causes an isothermal process with no temperature gradient, and no heat can be converted into power. The epoxy (42) can conduct heat to the temperature differential panel (1) instead; the electric efficiency of the temperature differential panel (1) is not affected.

Both proximal and distal ends of the temperature differential panel (1) are equipped with a first, second conductive cords (6a, 6b) which are able to discharge positive and negative charges of the current power generation device (2) respectively.

The first conductive cord (6a) is connected to the proximal end of the current power generation device (2) by the first conductor (20); the second conductive cord (6a) is connected to the distal end of the current power generation device (2) by the second conductor (21). Conductive cords (6a, 6b) are connected to the first conductor (20) and the second conductor (21) made of different metals or alloys. The electric charging points (22a, 22b) bridge both ends of the first, second conductors (20, 21) can discharge positive, negative charges based on Thomas Seebeck effects. Conductive cords (6a, 6b) also can be connected to other temperature differential panels (1) or devices in series or in parallel to increase current power generation output.

Materials of the first conductor (20) and the second conductor (21) can be selected from one of the following: chromium-magnesium alloy, aluminum-magnesium alloy, nickel-copper alloy, iron, platinum-rhodium alloy, and platinum. Some metals as mentioned above are common use in the industries. When those metals or alloys are available as thermo-electric materials may reduce cost of production under temperature range from −273° C. to 300° C. It is more weather-tolerable and accessible than the temperature range (from normal room temperature up to 250° C.) of the conventional thermo-electric modules.

Meanwhile, the first conductor (20) and second conductor (21) are metals or alloys further can be processed through chemical alloying method to provide nanometer sized thermoelectric materials. That is easy to implement than conventional melting process. Thermo-electric materials can be crystallized into nanometer sized materials with high surface area than bulk materials; furthermore, electrons in those surface areas are confined in one or more dimensions with quantum confinement effect. The quantum confinement occurs when one or more of the dimensions of a nanometer material made very small so that it approaches the size of an exciton in bulk crystal called the Bohr exciton radius. Therefore it has positive effects for generating power than materials nowadays. In addition, processed through micro-scale treatment facilitates laminating metal membranes on chips. Thereby, quantities of the temperature differential panels (1) aggregate enough within a limited surface area can improve electric efficiency.

### Second Embodiment

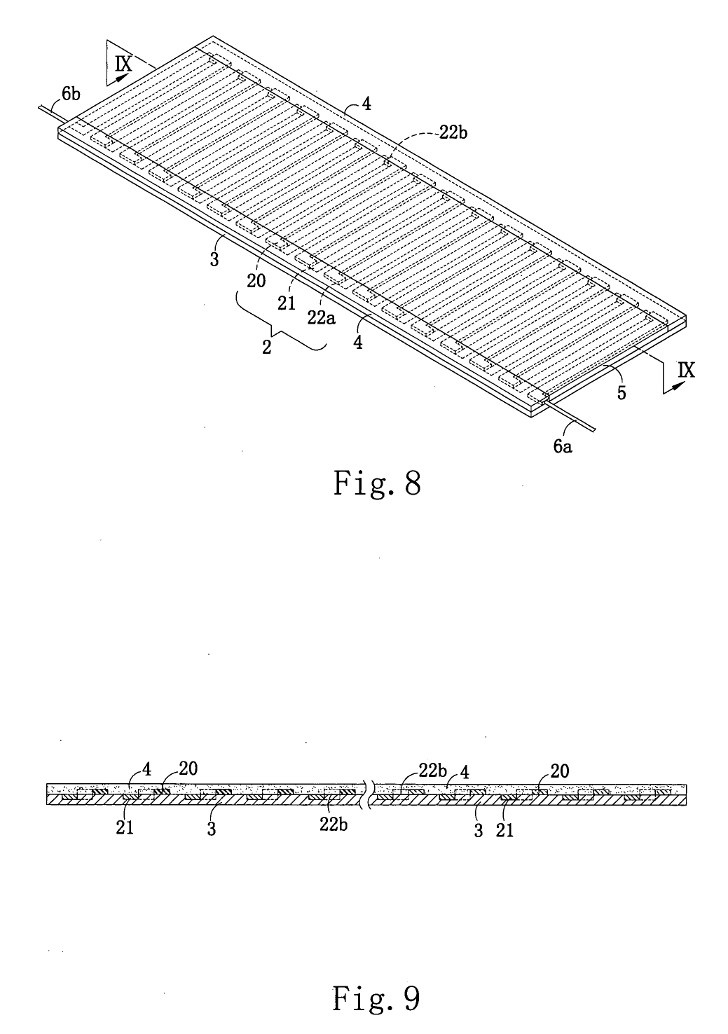

As shown in FIGS. 8˜9, a second embodiment of a plurality of the temperature differential panels of the invention are illustrated. The plurality of the temperature differential panels comprises:

A silicone-on-insulator substrate (3);

A current power generation device (2) is composed of a plurality of first conductors (20) and a plurality of second conductors (21) made of different metals or alloys, each of the first conductors (20) are alternatively and approximately in parallel to each of the second conductors (21) arranged on an upper surface of the silicone-on-insulator substrate (3). While both ends of each first, second conductors are connected to each other to form electric charging points (22a, 22b) to bridge the first, second conductors (20, 21) in parallel. Other than the electric charging points (22a, 22b) intermittently formed on both lateral sides respectively, at least, the first, second conductors can be insulated from each other by air.

Two thermal conductors (4) flanged on both lateral sides of the current power generation device (2) to shield all the electric charging points (22a, 22b); and a thermal insulator (5) shields the first conductors (20) and second conductors (21) arrayed between the electric charging points (22a, 22b).

The first, second conductors (20, 21) incorporated to the same upper surface of the silicone-on-insulator substrate (3) can be manufactured once for all by lamination, further can be integrated with others to form temperature differential panels array outputting significant quantities of current power. Since functions and materials of the thermal conductors (4) and the thermal insulators (5) are described in the first embodiment, there has no more description in detail about them.

Since the first conductors (20) and the second conductors (21) made from metal membranes are disposed to the silicone-on-insulator substrate by lamination; by which the temperature differential panel (1) can be minimized to a tiny chip with an improved electric efficiency. Thereby, more of the first and second conductors (20, 21) with more electric charging points (22a, 22b) can be aggregated sufficiently in a limited area as temperature differential panels array outputting significant quantities of current power. The temperature differential panels array can meet the requirement of renewable electricity generated and consumed standard to provide current power larger than a few temperature differential panels.

The thermal conductor (4) is epoxy contained aluminum oxide, or silicon with super conductivity. The epoxy filled in a gap between the first, second conductors (20, 21) protects electric charging points (22a, 22b) from inflicting damages. In addition, it is easy to manufacture the temperature differential panel (1).

Proximal and distal ends of the temperature differential panel (1) are equipped with a first, and second conductive cords (6a, 6b) are able to discharge positive and negative charges of current power generation device (2) respectively.

The first conductive cord (6a) connected to the proximal end of the current power generation device (2) by the first conductor (20), the second conductive cord (6b) connected to the distal end of the current power generation device (2) by the second conductor (21).

### Third Embodiment

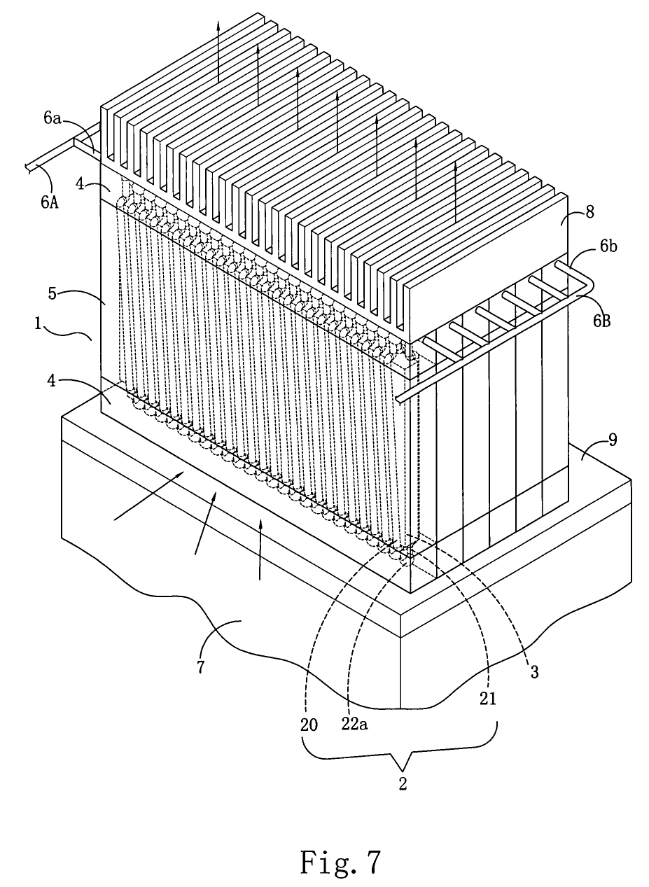

As shown in FIG. 7, a schematic view of a temperature differential accumulator characterized in that:

A plurality of temperature differential panels (1) disposed on an upper surface of a substrate (9), pairs of conductive cords (6a, 6b) discharge positive, negative charges from right and left ends of the current power generation devices (2) respectively, as shown in FIG. 7, major conductive cord (6A) and major conductive cord (6B) can be formed separately by each of the conductive cords (6a, 6b) joined together respectively to discharge positive, negative charges.

The temperature differential panels (1) can be connected in parallel by the conductive cords (6a, 6b). One of the thermal conductors (4) flanged on a bottom side of the temperature differential panels (1) are disposed to an upper surface of the substrate (9), where the temperature differential panels (1) can be held upright on the substrate (9) supported by a heater (7) such as an engine, or boiler. While the other of the thermal conductors (4) flanged on a top side of the temperature differential panels (1) are equipped with a fan (8), where a temperature gradient is provided due to both bottom and top sides of thermal conductors (4) are circulated air in different temperatures. Thereby, the electric charging points (22a, 22b) on both bottom and top side of the temperature differential panel (1) are thermally insulated and operated in different temperatures. A thermoelectric couple effect is therefore happened between the first, second conductors (20, 21). Thus, positive and negative charges (i.e. anions and cations) of the first, second conductors (20, 21) moved and aggregated sufficiently to form a significant current power generation with high electric efficiency.

As mentioned above, the temperature differential panel (1) is already described in detail in the first embodiment; more temperature differential panels (1) can work tolerably and are feasible to form a temperature differential accumulator to output significant quantities current power with an expanded temperature range from −273° C. to 300° C. The temperature differential accumulator is suitable for renewable power generated such as geothermal generation, solar power industry, fuel batteries etc., without mechanical noises, public hazardous materials, pollutions, but timely repairs.

### Fourth Embodiment

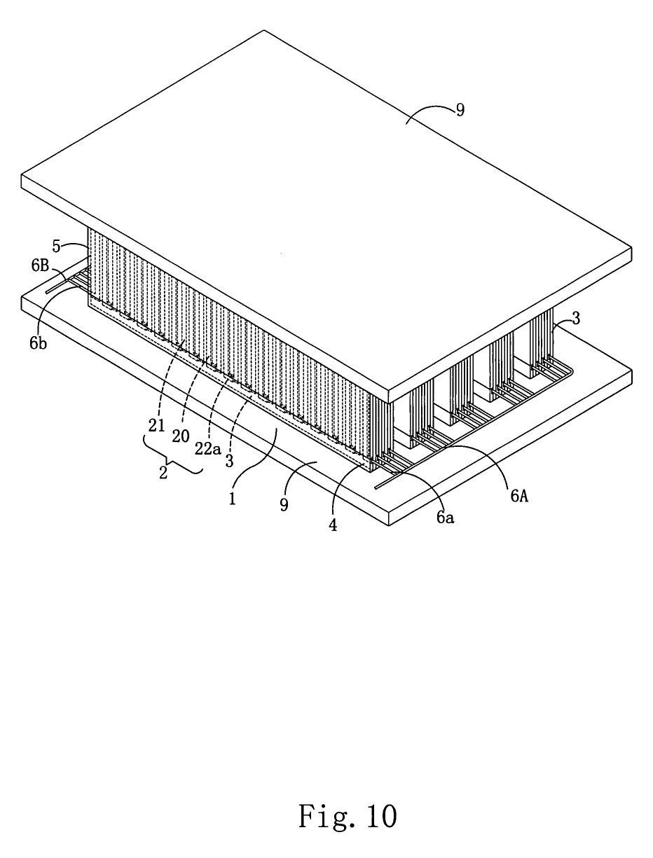

As shown in FIG. 10, a fourth embodiment of the invention is illustrated. First, second conductors (20, 21) on the temperature differential panel (1) made of metal membranes can further reduce dimensions of the temperature differential panel (1) with electric efficiency by lamination. Furthermore, substrates (9) can be fixed to thermal conductors (4) on both top and bottom sides of the temperature differential panel (1). It facilitates aggregating more temperature differential panels with more electric charging points (22a, 22b) bridge the first, second conductors (20, 21) as a temperature differential accumulator to output significant quantities of current power.

As mentioned above, the temperature differential panel (1) as described in the second embodiment, there has no more description in detail. It is suitable for general moderate to small devices due to the temperature differential panels (1) likely chips can be incorporated with one another to enlarge scope of application. In our daily life, where has heat or obvious temperature difference, it may provide renewable power generated to reduce carbon dioxide emission and energy consumption.

Substrate (9) is made of material of higher heat transfer coefficient can absorb or emit heat promptly to improve electric efficiency to the temperature differential panel.

What is claimed:

1. A temperature differential panel comprises:
a sheet-like insulation (3); and
a current power generation device (2) consists of a plurality of first conductors (20) and a plurality of second conductors (21) made of different metals or alloys, the first conductors (20) and second conductors (21) are disposed to a top and a bottom of the sheet-like insulation (3) respectively; both ends of each the first conductors (20) are connected to both ends of each the second conductors (21) at both lateral sides of the sheet-like insulation (3) respectively to form electric charging points (22a, 22b).

2. A temperature differential panel (1) as claim 1 claimed wherein the temperature differential panel (1) has two thermal conductors (4) flanged along both lateral sides of the sheet-like insulation (3) shielding the electric charging points (22a, 22b); and a thermal insulator (5) shielding the first conductors (20) and second conductors (21) between two thermal conductors (4) except the electric charging points (22a, 22b).

3. A temperature differential panel (1) as claim 2 claimed wherein a thermal conductor (4) is composed of an insulation layer (41) shields the electric charging points (22a, 22b), a thermal conduction layer (40) shields the insulation layer (41), a thermally conductive adhesive (42) filled up between the thermal conductive layer (40) and the electric charging points (22a, 22b).

4. A temperature differential panel (1) as claim 1 claimed wherein both ends of the temperature differential panel (1) have a first and a second conductive cords (6a, 6b) to discharge positive and negative charges of the current power generation device (2).

5. A temperature differential panel (1) as claim 4 claimed wherein the first conductive cord (6a) connected to a proximal end of the current power generation device (2) by the first conductor (20), and a second conductive cord (6b) connected to a distal end of the current power generation device (2) by the second conductor (21).

6. A temperature differential panel (1) as claim 1 claimed wherein materials of the first conductor (20) and the second conductor (21) are selected from one of following: chromium-magnesium alloy, aluminum-magnesium alloy; nickel-copper alloy, iron, platinum-rhodium alloy, and platinum.

7. A temperature differential panel (1) as claim 1 claimed wherein materials of the first conductor (20) and the second conductor (21) are metals and alloys processed through nano-scale or micro-scale treatments.

8. A temperature differential panel (1) characterized in that:
a sheet-like insulation (3);
a current power generation device (2) is composed of a plurality of first conductors (20) and a plurality of second conductors (21) made of different metals or alloys, each of the first conductors (20) are alternatively arranged approximately in parallel to each of the second conductors (21) in order disposed to an upper side of the insulator (3), both ends of each the first conductors (20) are connected to both ends of each the second conductors (21) respectively to form electric charging points (22a, 22b);
two thermal conductors (4) flanged both lateral sides of the sheet-like insulation (3) shielding the electric charging points (22a, 22b); and a thermal insulator (5) shielding the first conductors (20) and the second conductors (21) between two thermal conductors (4) except the electric charging points (22a, 22b).

9. A temperature differential panel (1) as claim 8 claimed wherein materials of the first conductors (20) and the second conductors (21) are selected from one of following: chromium-magnesium alloy, aluminum-magnesium alloy; nickel-copper alloy, iron, platinum-rhodium alloy, and platinum.

10. A temperature differential panel (1) as claim 8 claimed wherein the materials of first conductor (20) and second conductor (21) are metals or alloys processed through nano-scale or micro-scale treatments.

11. A temperature differential panel (1) as claim 8 claimed wherein all the first conductors (20) and all the second conductors (21) are shaped as distinct metal membranes show laminated structure.

12. A temperature differential panel (1) as claim 8 claimed wherein a thermal conductor (4) consists of epoxy contained aluminum oxide, or silicon to provide excellent electrical conductivity.

13. A temperature differential panel (1) as claim 8 claimed wherein the temperature differential panel (1) has a first and a second conductive cords (6a, 6b) at a proximal and distal ends to discharge positive, negative charges of the current power generation device (2) respectively.

14. A temperature differential panel (1) as claim 13 claimed wherein the first conductive cord (6a) is connected to a proximal end of the current power generation device (2) by the first conductor (20), the second conductive cord (6b) is connected to a distal end of the current power generation device (2) by the second conductor (21).

15. A temperature differential accumulator characterized in that:
a plurality of temperature differential panels (1) disposed to an upper surface of a substrate (9), the conductive cords (6a, 6b) connected to right and left ends of the current power generation devices (2) discharging positive and negative charges respectively can be joined together to form major conductive cords (6A, 6B) discharging positive and negative charges.

16. A temperature differential accumulator as claim 15 claimed wherein the temperature differential panel is the same introduced in claim 1.

17. A temperature differential accumulator as claim 15 claimed wherein the temperature differential panel is the same introduced in claim 8.

18. A temperature differential accumulator as claim 15 claimed wherein materials of the substrate (9) have high coefficient of heat transferring.

19. A temperature differential accumulator as claim 15 claimed wherein the substrate (9) can be added to the thermal conductor (4) on top of the temperature differential panels (1).
